(19) United States
(12) Patent Application Publication
(10) Pub. No.: US 2024/0224693 A1
(43) Pub. Date: Jul. 4, 2024

(54) DISPLAY DEVICE

(71) Applicant: LG Display Co., Ltd., Seoul (KR)

(72) Inventors: KyooHo LEE, Gyeonggi-do (KR); JaeYoung OH, Gyeonggi-do (KR); KyoungJin NAM, Gyeonggi-do (KR)

(73) Assignee: LG Display Co., Ltd., Seoul (KR)

(21) Appl. No.: 18/394,158

(22) Filed: Dec. 22, 2023

(30) Foreign Application Priority Data
Dec. 30, 2022 (KR) 10-2022-0191308

(51) Int. Cl. H10K 59/38; H10K 59/122; H10K 59/80

(52) U.S. Cl. CPC H10K 59/38; H10K 59/122; H10K 59/80518; H10K 59/8731; H10K 59/8792; H10K 2102/331

(57) ABSTRACT

A display device includes a substrate including at least one of red, green, and blue subpixels, a light emitting element including a first electrode disposed on the substrate, a light emitting layer disposed on the first electrode, and a second electrode disposed on the light emitting layer, a bank layer having an opening exposing at least a portion of the first electrode, a black matrix disposed in a trench provided in the bank layer and protruding beyond an upper surface of the bank layer, a light conversion layer disposed on the light emitting element and including quantum dots, an auxiliary layer disposed on the light conversion layer, and a color filter layer disposed on the auxiliary layer and having a color corresponding to each of the at least one subpixel.

### CROSS-REFERENCE TO RELATED APPLICATION

This application claims the priority of Korean Patent Application No. 10-2022-0191308, filed on Dec. 30, 2022, which is hereby incorporated by reference in its entirety.

### BACKGROUND

### Field of the Disclosure

The present disclosure relates to a display device.

### Description of the Background

Display devices are widely used as display screens for laptop computers, tablet computers, smartphones, portable display devices, and portable information devices, as well as for televisions or monitors.

Display devices may be divided into reflective display devices and emissive display devices. The reflective display device is a display device that displays information by reflecting natural light or light from an external light source of the display device to the display device. The emissive display device displays information using the light generated from light emitting elements or a light source embedded in the display device.

### SUMMARY

The conventional display device has the adjacent pixel emission issue that arises as the light emitted from a light emitting element is guided and leaks to the adjacent pixel due to multiple transparent layers disposed between the light emitting element and the light conversion layer including quantum dots.

The present disclosure is to provide a display device capable of mitigating light leakage by reducing the cell gap between the light emitting element and the color filter layer by having a structure in which a black matrix is inserted into a trench provided in the bank layer.

The present disclosure is also to provide a display device capable of enhancing light extraction efficiency by increasing light conversion efficiency in quantum dots included in the light conversion layer as each of the auxiliary layer and the second electrode has a structure including a semi-transmissive metal material.

The present disclosure is also to provide a display device requiring a reduction in pixel size and an increase in the number of pixels through enhancement of the viewing field by reducing the external propagation distance of light by having a structure in which a black matrix is inserted into a trench provided in the bank layer.

The present disclosure is also to provide a display device having enhanced ability to trap moisture as the auxiliary layer has a structure containing a large amount of magnesium (Mg).

The present disclosure is also to provide a display device capable of low power consumption and process optimization.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a substrate including at least one of red, green, and blue subpixels, a light emitting element including a first electrode disposed on the substrate, a light emitting layer disposed on the first electrode, and a second electrode disposed on the light emitting layer, a bank layer having an opening exposing at least a portion of the first electrode, a black matrix disposed in a trench provided in the bank layer and protruding beyond an upper surface of the bank layer, a light conversion layer disposed on the light emitting element and including quantum dots, an auxiliary layer disposed on the light conversion layer, and a color filter layer disposed on the auxiliary layer and having a color corresponding to each of the at least one subpixel.

Aspects of the present disclosure may provide the display device, wherein the second electrode and the auxiliary layer include silver (Ag) and magnesium (Mg), and wherein an atomic ratio of Mg included in the auxiliary layer is larger than an atomic ratio of Mg included in the second electrode.

In another aspect of the present disclosure, a display device includes a substrate including a light emitting element, a bank layer disposed on the substrate and defining an opening overlapping the light emitting element, the opening having an upper surface and a lower surface smaller in width than the upper surface, a first quantum dot barrier layer disposed on the light emitting element and the bank layer, a second quantum dot barrier layer disposed to be spaced apart from the first quantum dot barrier layer, an auxiliary layer disposed on the second quantum dot barrier layer, a color filter layer disposed on the auxiliary layer, and a light conversion layer disposed between the first quantum dot barrier layer and the second quantum dot barrier layer, wherein the light conversion layer includes quantum dots which fill from the lower surface of the opening to the upper surface of the opening.

According to aspects of the present disclosure, there may be provided a display device capable of mitigating light leakage by reducing the cell gap between the light emitting element and the color filter layer by having a structure in which a black matrix is inserted into a trench provided in the bank layer.

According to aspects of the present disclosure, there may be provided a display device capable of enhancing light extraction efficiency by increasing the light conversion efficiency in quantum dots included in the light conversion layer.

According to aspects of the present disclosure, there may be provided a display device requiring a reduction in pixel size and an increase in the number of pixels through enhancement of the viewing field by reducing the external propagation distance of light.

According to aspects of the present disclosure, there may be provided a display device capable of low power consumption and process optimization.

According to aspects of the present disclosure, there may be provided a display device having enhanced ability to trap moisture by containing a large amount of Mg in the auxiliary layer.

It is to be understood that both the foregoing general description and the following detailed description are exemplary and explanatory and are intended to provide further explanation of the disclosure as claimed.

### BRIEF DESCRIPTION OF THE DRAWINGS

The above and other features and advantages of the disclosure will be more clearly understood from the following detailed description, taken in conjunction with the accompanying drawings, in which:

FIG. 1 is a view schematically illustrating a system configuration of a display device according to example aspects of the present disclosure;

FIG. 2 is a view illustrating a schematic planar structure of a pixel structure disposed on a display panel of a display device according to example aspects of the present disclosure;

FIG. 3 is a cross-sectional view taken along line A-A′ of FIG. 2 to which a structure according to example aspects of the present disclosure does not applies;

FIG. 4 is a cross-sectional view taken along line A-A′ of FIG. 2 to which a structure according to example aspects of the present disclosure applies; and

FIG. 5 is a cross-sectional view illustrating a structural feature of a display device to which a structure according to example aspects of the present disclosure is applied.

### DETAILED DESCRIPTION

In the following description of examples or aspects of the present disclosure, reference will be made to the accompanying drawings in which it is shown by way of illustration specific examples or aspects that may be implemented, and in which the same reference numerals and signs may be used to designate the same or like components even when they are shown in different accompanying drawings from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only may the first element “be directly connected or coupled to” or “directly contact or overlap” the second element, but a third element may also be “interposed” between the first and second elements, or the first and second elements may “be connected or coupled to”, “contact or overlap”, etc. each other via a fourth element. Here, the second element may be included in at least one of two or more elements that “are connected or coupled to”, “contact or overlap,” etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e. g., level, range, etc.) include a tolerance or error range that may be caused by various factors (e. g., process factors, internal or external impact, noise, etc.) even when a relevant description is not specified. Further, the term “may” fully encompass all the meanings of the term “can.”

Hereinafter, various aspects of the present disclosure are described in detail with reference to the accompanying drawings.

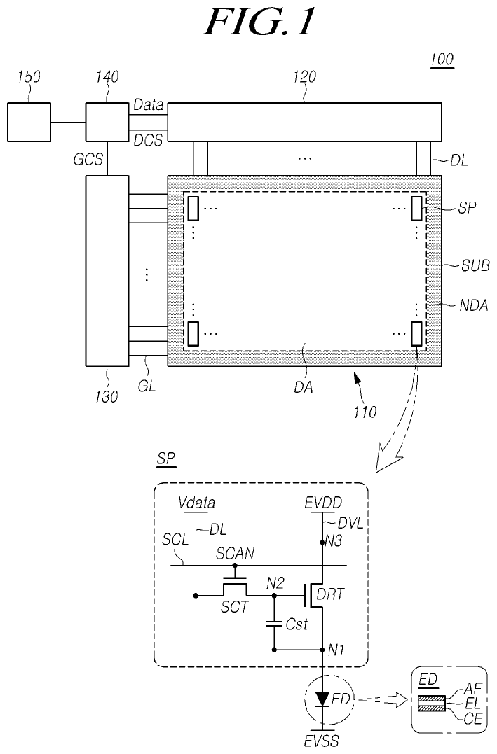

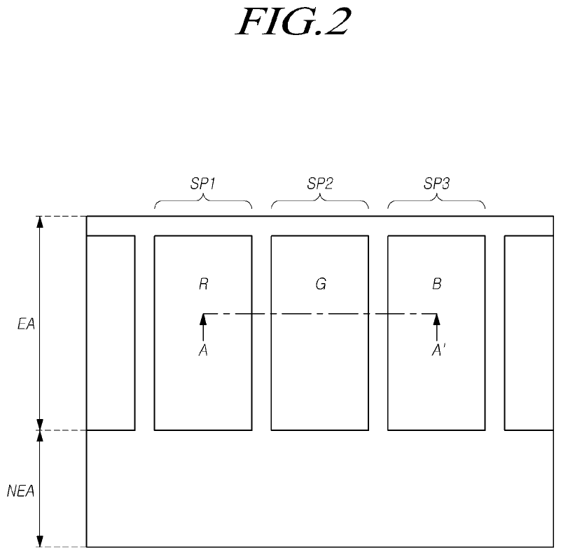

FIG. 1 is a view schematically illustrating a system configuration of a display device according to example aspects of the present disclosure. FIG. 2 is a view illustrating a schematic planar structure of a pixel structure disposed on a display panel of a display device according to example aspects of the present disclosure.

Referring to FIG. 1, a display driving system of a display device 100 according to example aspects of the present disclosure may include a display panel 110 and display driving circuits for driving the display panel 110.

The display panel 110 may include a display area DA in which images are displayed and a non-display area NDA in which no image is displayed. The display panel 110 may include a plurality of subpixels SP disposed on a substrate SUB for image display. The display panel 110 may include a plurality of signal lines disposed on the substrate SUB. For example, the plurality of signal lines may include data lines DL, gate lines GL, driving voltage lines, and the like.

Each of the plurality of data lines DL is disposed while extending in a first direction (e.g., a column direction or a row direction), and each of the plurality of gate lines GL is disposed while extending in a direction crossing the first direction.

The display driving circuits may include a data driving circuit 120, a gate driving circuit 130, and a controller 140 controlling the data driving circuit 120 and the gate driving circuit 130.

The data driving circuit 120 may output data signals (also referred to as data voltages) corresponding to an image signal to the plurality of data lines DL. The gate driving circuit 130 may generate gate signals and output the gate signals to the plurality of gate lines GL. The controller 140 may convert the input image data input from an external host 150 to meet the data signal format used in the data driving circuit 120 and supply the converted image data to the data driving circuit 120.

The data driving circuit 120 may include one or more source driver integrated circuits. For example, each source driver integrated circuit may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may be connected to the display panel 110 by a tape automatic bonding (TAB) method, connected to a bonding pad of the display panel 110 by a COG or COP method, connected to the display panel 110 by a COF method, or may be formed in the non-display area NDA of the display panel 110 by a gate in panel (GIP) method.

Referring to FIG. 1, in the display device 100 according to example aspects of the present disclosure, each subpixel SP may include a light emitting element ED and a pixel driving circuit SPC for driving the light emitting element ED. The pixel driving circuit SPC may include a driving transistor DRT, a scan transistor SCT, and a storage capacitor Cst.

The driving transistor DRT may control a current flowing to the light emitting element ED to drive the light emitting element ED. The scan transistor SCT may transfer the data voltage Vdata to the second node N2 which is the gate node of the driving transistor DRT. The storage capacitor Cst may be configured to maintain a voltage for a predetermined period of time.

The light emitting element ED may include an anode electrode AE and a cathode electrode CE, and a light emitting layer EL positioned between the anode electrode AE and the cathode electrode CE. The anode electrode AE may be a pixel electrode involved in forming the light emitting element ED of each subpixel SP and may be electrically connected to the first node N1 of the driving transistor DRT. The cathode electrode CE may be a common electrode involved in forming the light emitting elements ED of all the subpixels SP, and a ground voltage EVSS may be applied thereto.

For example, the light emitting element ED may be an organic light emitting diode OLED, an inorganic light emitting diode (LED), or a quantum dot light emitting element, which is a self-luminous semiconductor crystal.

If the display device 100 according to aspects of the present disclosure is an OLED display, each subpixel SP may include an organic light emitting diode (OLED), which by itself emits light, as the light emitting element. If the display device 100 according to aspects of the present disclosure is a quantum dot display, each subpixel SP may include a light emitting element formed of quantum dots, which is a self-luminous semiconductor crystal. If the display device 100 according to aspects of the present disclosure is a micro LED display, each subpixel SP may include a micro LED, which is self-emissive and formed of an inorganic material, as the light emitting element.

The driving transistor DRT is a transistor for driving the light emitting element ED, and may include a first node N1, a second node N2, and a third node N3. The first node N1 may be a source node or a drain node, and may be electrically connected to the anode electrode AE of the light emitting element ED. The second node N2 is a gate node and may be electrically connected to the source node or drain node of the scan transistor SCT. The third node N3 may be a drain node or a source node, and may be electrically connected to a driving voltage line DVL that supplies the driving voltage EVDD. For convenience of description, in the example described below, the first node N1 may be a source node and the third node N3 may be a drain node.

The scan transistor SCT may switch the connection between the data line DL and the second node N2 of the driving transistor DRT. In response to the scan signal SCAN supplied from the scan line SCL which is a kind of the gate line GL, the scan transistor SCT may control connection between the second node N2 of the driving transistor DRT and a corresponding data line DL among the plurality of data lines DL.

The storage capacitor Cst may be configured between the first node N1 and second node N2 of the driving transistor DRT.

The structure of the subpixel SP illustrated in FIG. 1 is merely an example for description, and may further include one or more transistors, or one or more storage capacitors. The plurality of subpixels SP may have the same structure, or some of the plurality of subpixels SP may have a different structure. Each of the driving transistor DRT and the scan transistor SCT may be an n-type transistor or a p-type transistor.

The display device 100 according to aspects of the present disclosure may have a top emission structure or a bottom emission structure. The top emission structure is described below as an example. For example, in the top emission structure, the anode electrode AE may be a reflective metal, and the cathode electrode CE may be a transparent conductive film.

Referring to FIG. 2, a display device 100 according to example aspects includes a plurality of subpixels SP1 to SP3, and each subpixel SP1 to SP4 includes an emission area EA that emits light for displaying and a non-emission area NEA other than the emission area.

The display device 100 according to aspects includes a bank layer to partition each of the subpixels SP1 to SP4.

In the subpixel structure of the display device 100 according to aspects of the present disclosure also includes a “signal line connection structure” that is related to connection of each subpixel to several signal lines, such as the data line DL, gate line GL, driving voltage line DVL, and reference voltage line.

The signal lines may include not only the data line DL for supplying the data voltage Vdata to each subpixel and the gate line GL for supplying the scan signal but also a reference voltage line for supplying the reference voltage Vref to each subpixel and a driving voltage line DVL for supplying the driving voltage EVDD.

In the disclosure and drawings, the subpixel connected to the 4n−3th data line DL(4n−3), the subpixel connected to the 4n−2th data line DL(4n−2), the subpixel connected to the 4n−1th data line DL(4n−1), and the subpixel connected to the 4nth data line DL(4n) may be, e.g., a red (R) subpixel, a green (G) subpixel, a blue (B) subpixel, and a white (W) subpixel, respectively.

However, without limitations thereto, the red (R) subpixel, the green (G) subpixel, the blue (B) subpixel, and the white (W) subpixel may be arranged in other various orders. A pixel structure having the order of the red (R) subpixel SP1, the green (G) subpixel SP2, the blue (B) subpixel SP3, and the white (W) subpixel SP4 is described below.

As described above, when the default unit of the signal line connection structure includes four subpixels SP1 to SP4 connected to four data lines DL(4n−3), DL(4n−2), DL(4n−1), and DL(4n), one reference voltage line RVL for supplying the reference voltage Vref and two driving voltage lines DVL for supplying the driving voltage EVDD may be formed for the four subpixels SP1 to SP4. The four data lines DL(4n−3), DL(4n−2), DL(4n−1), and DL(4n) are connected to the four subpixels SP1 to SP4, respectively. Further, one gate line GL(m) (where 1≤m≤M) is connected to the four subpixels SP1 to SP4.

In the display device 100 according to aspects of the present disclosure, the light emitting element ED emitting white (W) or blue (B) light is commonly disposed in each subpixel, and a red (R) color filter, a blue (B) color filter, and a green (G) color filter are disposed in the red (R) subpixel SP1, the blue (B) subpixel SP3, and the green (G) subpixel SP2, respectively. No separate color filter is disposed in the white (W) subpixel.

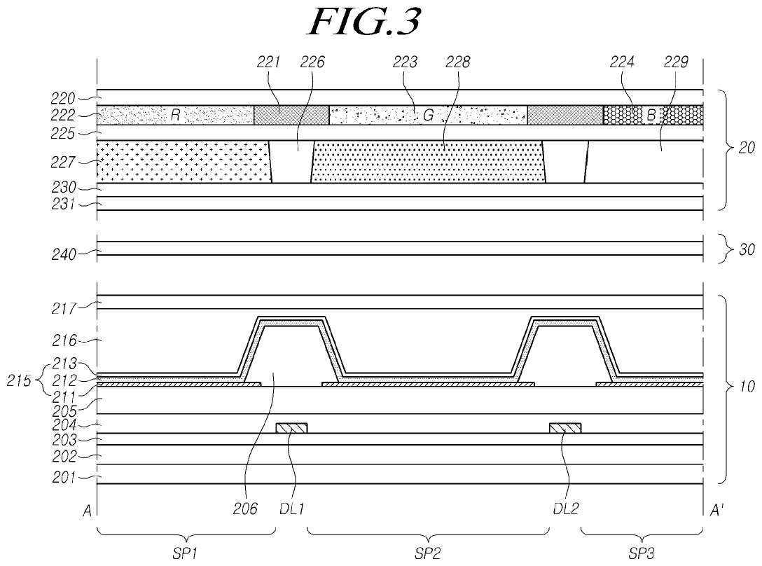

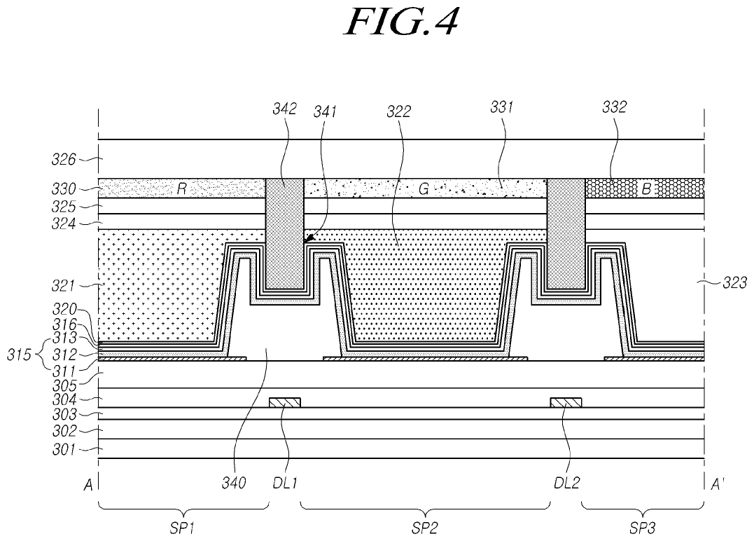

FIG. 3 is a cross-sectional view illustrating a conventional display device, and FIG. 4 is a cross-sectional view illustrating a display device according to example aspects of the present disclosure. Specifically, FIG. 3 is a cross-sectional view taken along line A-A′ of FIG. 2 to which a structure according to example aspects of the present disclosure does not applies. FIG. 4 is a cross-sectional view taken along line A-A′ of FIG. 2 to which a structure according to example aspects of the present disclosure applies.

Referring to FIG. 3, in the conventional display device, an upper unit 20 including the light conversion layer 227, 228 and 229 and the color filter layer 222, 223, and 224, and a lower unit 10 including the light emitting element 215 and the thin film transistor (not shown) are manufactured by separate processes, and then the upper unit 20 and the lower unit 10 are attached to each other using an adhesive unit 30.

Referring to FIG. 3, a QD bank 226 is an essential component to generate the light conversion layer 227, 228, and 229 for each subpixel, and an additional process for generating the QD bank 226 as well as the black matrix 221 of the color filter layer 222, 223, and 224 is required.

Further, a plurality of layers are present between the light emitting element 215 and the light conversion layer 227, 228, and 229. For example, various layers, such as a filling layer 216, a lower encapsulation layer 217, an adhesive layer 240, an upper encapsulation layer 231, and a quantum dot protection layer 230 are included, and these layers are transparent layers through which the light from the light emitting element 215 may be transmitted.

Due to the plurality of transparent layers disposed between the light emitting element 215 and the light conversion layer 227, 228, and 229, light may leak to adjacent pixels as the result of the light guide effect of blue light output from the light emitting element 215, causing the adjacent pixels to emit light.

Referring to FIG. 4, a display device 100 according to example aspects of the present disclosure may include a substrate 301 including a light emitting element 315, a bank layer 340 disposed on the substrate 301 and defining an opening overlapping the light emitting element 315, a trench 341 including a lower surface disposed to have a predetermined depth from an upper surface of the bank layer 340 and a sidewall portion connecting the lower surface and the upper surface, a black matrix 342 protruding beyond the upper surface of the bank layer 340 and seated in the trench 341, a light conversion layer 321 and 322 including quantum dots and disposed on the light emitting element 315, and an auxiliary layer 325 disposed on the light conversion layer 321 and 322.

A plurality of subpixels may be disposed on the substrate 301. The substrate 301 may include at least one of red, green, and blue subpixels.

The substrate 301 may be selected as a material for forming an element having excellent mechanical strength or dimensional stability. The substrate 301 may be not only a glass substrate, but also a plastic substrate including polyethylene terephthalate (PET), polyethylene naphthalate (PEN), polyimide, or the like.

The buffer layer 302 serves to protect a thin film transistor (not shown) formed in a subsequent process from impurities such as alkali ions flowing out of the substrate 301. The buffer layer 302 may be a single layer of silicon oxide (SiOₓ) or silicon nitride (SiNx) or multiple layers thereof.

A passivation layer 303 may be disposed on the buffer layer 302.

The passivation layer 303 is an insulation film for protecting elements thereunder, and may be a single layer of silicon oxide (SiOₓ) or silicon nitride (SiNx) or multiple layers thereof. Also, the passivation layer 303 may be omitted.

A plurality of signal lines DL1 and DL2 may be disposed on the passivation layer 303, and an insulation layer 304 may be disposed on the plurality of signal lines DL1 and DL2.

The insulation layer 304 is an insulation film for protecting the signal lines thereunder, and may be a single layer of silicon oxide (SiOₓ) or silicon nitride (SiNx) or multiple layers thereof. Also, the insulation layer 304 may be omitted.

An overcoat layer 305 may be disposed on the insulation layer 304.

The overcoat layer 305 may be formed of an organic film such as an acryl resin, an epoxy resin, a phenolic resin, a polyamide resin, a polyimide resin, or the like. The overcoat layer 305 may planarize the surface of the substrate 301 on which the thin film transistor (not shown) and various signal lines are formed.

The light emitting element 315 may be disposed on the overcoat layer 305. For example, the light emitting element 315 may be an organic light emitting diode OLED, an inorganic light emitting diode (LED), or a quantum dot light emitting element, which is a self-luminous semiconductor crystal.

Described below is an example in which the light emitting element 315 is an organic light emitting diode (OLED), but the disclosure is not limited thereto.

The light emitting element 315 may include a first electrode 311 disposed on the substrate 301, a light emitting layer 312 disposed on the first electrode 311, and a second electrode 313 disposed on the light emitting layer 312.

An encapsulation layer 316 in which a plurality of organic films and inorganic films are stacked may be further formed on the light emitting element 315.

The first electrode 311 is a pixel electrode serving as an anode, and may be independently disposed in each of the subpixels.

The first electrode 311 may include a reflective metallic material having a low work function and excellent reflection efficiency.

For example, the reflective metal included in the first electrode 311 may include one of aluminum (Al), silver (Ag), copper (Cu), magnesium (Mg), platinum (Pt), gold (Au), nickel (Ni), neodymium (Nd), iridium (Ir), and chromium (Cr), or one of alloys including at least one thereof.

For example, the first electrode 311 may be formed in a multilayer structure of any one of a stacked structure (Ti/Al/Ti) of aluminum (Al) and titanium (Ti), a stacked structure (ITO/Al/ITO) of aluminum (Al) and ITO, an alloy of APC (Ag/Pd/Cu), and a stacked structure (ITO/APC/ITO) of APC alloy and ITO, or may be formed in a single layer structure or a multilayer structure of at least one of aluminum (Al), silver (Ag), copper (Cu), magnesium (Mg), platinum (Pt), gold (Au), nickel (Ni), neodymium (Nd), iridium (Ir), chromium (Cr), and alloys thereof.

Further, the first electrode 311 may include a reflective electrode disposed on the substrate 301 and a transparent electrode disposed on the reflective electrode. The reflective electrode may be the above-described reflective metal, and the transparent electrode may include transparent conductive oxide (TCO) such as indium tin oxide (ITO), indium zinc oxide (IZO), indium gallium zinc oxide (IGZO), or the like.

The light emitting layer 312 may be an organic light emitting layer 312. The organic light emitting layer 312 may include multiple layers of a hole injection layer, a hole transport layer, a light emitting material layer, an electron transport layer, and an electron injection layer to increase light emission efficiency.

The second electrode 313 is a common electrode serving as a cathode, and may be commonly disposed in all subpixels SP1 to SP3.

The second electrode 313 may be a semi-transmissive electrode including a semi-transmissive metal or a transparent electrode.

The second electrode 313 may include one of aluminum (Al), silver (Ag), copper (Cu), magnesium (Mg), platinum (Pt), gold (Au), nickel (Ni), chromium (Cr), titanium (Ti), tungsten (W), tantalum (Ta), cobalt (Co), iron (Fe), and molybdenum (Mo), or one of alloys including at least one thereof.

For example, the second electrode 313 may be an alloy including silver (Ag) and magnesium (Mg). When the second electrode 313 is an Ag—Mg alloy, the atomic ratio of Ag:Mg may be 10:1 to 9:1.

An encapsulation layer 316 in which a plurality of organic films and inorganic films are stacked may be disposed on the light emitting element 315, and specifically disposed on the second electrode 313 in the light emitting element 315.

The encapsulation layer 316 may be formed by alternately stacking a plurality of inorganic films and organic films. For example, the inorganic film may be formed of at least one of aluminum oxide (AlₓOₓ), silicon oxide (SiOₓ), SiNx, SiO_{N}, and LiF to primarily block penetration of external moisture or oxygen, but is not limited thereto. The organic film may secondarily block the penetration of external moisture or oxygen. The organic film serves as a buffer for relieving stress between layers due to bending of the display device 100 and may also serve to enhance planarization performance. Such an organic film may be formed of a polymer material such as an acrylic resin, an epoxy resin, polyimide, or polyethylene, but is not limited thereto.

A first quantum dot barrier layer 320 may be disposed on the encapsulation layer 316.

The light emitting layer 312 of the light emitting element 315 is very vulnerable to impurities, such as moisture or oxygen from the outside. Therefore, it is necessary to prevent the outgassing generated from the light conversion layer 321 and 322 including quantum dots from traveling toward the light emitting layer 312 of the light emitting element 315 in the manufacturing process or during use after manufacturing is done.

To that end, a first quantum dot barrier layer 320 may be interposed between the second electrode 313 and the light conversion layer 321 and 322.

The first quantum dot barrier layer 320 may be formed of an inorganic material such as silicon nitride (SiNx), silicon oxide (SiOₓ), silicon oxynitride (SiOₓN_{y}), or the like to prevent the outgassing from passing therethrough. The first quantum dot barrier layer 320 may be formed of a single layer or multiple layers thereof.

A bank layer 340 is disposed on the overcoat layer 305 and the first electrode 311. The first quantum dot barrier layer 320 may be disposed on the light emitting element 315 and the bank layer 340.

The bank layer 340 may define an opening overlapping the light emitting element 315. Further, the bank layer 340 may define an opening by exposing at least a portion of the first electrode 311. A width of a lower surface of the opening is smaller than a width of an upper surface of the opening.

The bank layer 340 may define an emission area of the display device 100, and thus may be referred to as a pixel defining film. The bank layer 340 may be an organic insulating material. For example, the bank layer 340 may be formed of a polyimide, acryl, or benzocyclobutene (BCB) resin, but is not limited thereto.

The trench 341 and the black matrix 342 may be disposed on the upper surface of the bank layer 340.

Referring to FIG. 4, the black matrix 342 may be disposed in the trench 341 provided in the bank layer 340.

The black matrix 342 may protrude beyond the upper surface of the bank layer 340 and may be seated in the trench 341. In other words, the black matrix 342 may be formed in the trench 341 of the bank layer 340 in a correct position, so that the bank layer 340 and the black matrix 342 may define the emission area of the display device 100.

The width of the upper surface of the black matrix 342 may not be greater than the width of the upper portion of the trench 341.

For example, the width of the upper surface of the black matrix 342 may be smaller than the width of the upper portion of the trench 341. In other words, the black matrix 342 may have a forward taper shape on the bank layer 340.

By applying the structure in which the black matrix 342 is deposited and inserted into the trench 341 provided in the bank layer 340, the cell gap between the light emitting element 315 and the color filter layer 330, 331, and 332 may be minimized to minimize light leakage.

Further, as the distance in which the light emitted from the light emitting element 315 travels outward decreases, it may be applied to display devices that require a reduction in pixel size and an increase in the number of pixels through enhancement of the field of view.

The light conversion layer 321 and 322 may be disposed on the first quantum dot barrier layer 320.

The light conversion layer 321 and 322 may convert light output from the light emitting element 315 into light of a color corresponding to each subpixel. The light conversion layer 321 and 322 may include quantum dots.

The light conversion layer 321 and 322 may include quantum dots of different sizes or types to convert light of the color corresponding to each subpixel.

The type of quantum dots included in the light conversion layer is not particularly limited. The light conversion layer may include quantum dots of a single layer structure including one or more of group III-V semiconductor nanocrystals and group II-VI semiconductor nanocrystals or quantum dots of a multilayer structure having a core/shell structure.

Quantum dots are nanoparticles and feature photoluminescence (PL) in which electrons excited to a high energy level by external light emit light while returning to a low energy level. This feature of quantum dots may be utilized to convert the wavelength of light emitted from the light source of the display device. In particular, since quantum dots emit light having different wavelengths depending on the diameter, the quantum dots may be applied to manufacture a display device having high color purity by precisely controlling the diameter in the manufacturing process of the quantum dots. However, there is an issue that quantum dots have low conversion efficiency of PL emission, and aspects of the present disclosure may address such an issue.

For example, the quantum dots may be included in the light conversion layer 321 and 322 by an inkjet method.

When using the inkjet method, if the structure in which the black matrix 342 is deposited and inserted into the trench 341 provided in the bank layer 340 is applied, the bank layers 340 for the light conversion layer 321 and 322 is heightened by the height of the black matrix 342, thus preventing quantum dots included in the light conversion layer 321 and 322 from overflowing into adjacent subpixels.

The quantum dots included in the light conversion layer 321 and 322 may fill from the lower surface of the opening to the upper surface of the opening. Specifically, the quantum dots may fill on the lower surface of the opening, higher than the upper surface of the bank layer 340 and fill lower than the upper surface of the black matrix 342.

Further, the second quantum dot barrier layer 324 may be provided on the lower surface of the auxiliary layer 325 to be spaced apart from the upper surface of the bank layer 340, and the quantum dots may fill up to an area where the bank layer 340 and the second quantum dot barrier layer 324 are spaced apart from each other. Further, the second quantum dot barrier layer 324 may be disposed to be spaced apart from the first quantum dot barrier layer 320.

The light conversion layer 321 and 322 may include a first light conversion layer, a second light conversion layer, and a light transmissive layer 323 or a third light conversion layer (not shown) according to respective subpixels.

When the light output from the light emitting element is blue light, the first light conversion layer 321 may convert the blue light output from the light emitting element into first light, and the first light may be red light. The second light conversion layer 322 may convert the blue light output from the light emitting element into second light, and the second light may be green light. The light transmissive layer 323 may transmit the blue light output from the light emitting element.

Since the auxiliary layer 325 and the second electrode 313 each include a semi-transmissive metal material, light output from the light emitting element 315 may be repeatedly reflected between the second electrode 313 including the semi-transmissive metal and the auxiliary layer 325, or may be repeatedly reflected between the first electrode 311 and the auxiliary layer 325, thereby increasing light conversion efficiency at quantum dots included in the light conversion layer 321 and 322 and hence enhancing the efficiency of emitted light. In other words, the light transmissive layer 323 may transmit blue light output from the light emitting element and emit light to the outside. The light transmissive layer 323 may be formed of a transparent material used in the overcoat layer 305, the passivation layer 303, and the buffer layer 302.

For example, the light conversion layer is a transparent organic layer and may include the same transparent organic material as the material forming the overcoat layer. When the light emitting element outputs blue light, the first light conversion layer 321 may include first quantum dots for converting blue light into red light in the transparent organic material, the second light conversion layer 322 may include second quantum dots for converting blue light into green light in the transparent organic material, and the light transmissive layer 323 may include only a transparent organic material or a scattering material without including quantum dots.

When the light output from the light emitting element is white light, the first light conversion layer 321 may convert the white light output from the light emitting element into first light, and the first light may be red light. The second light conversion layer 322 may convert the white light output from the light emitting element into second light, and the second light may be green light. The third light conversion layer (not shown) may convert the white light output from the light emitting element into third light, and the third light may be blue light.

For example, when the light emitting element outputs white light, the first light conversion layer 321 may include first quantum dots for converting white light into red light in the transparent organic material, the second light conversion layer 322 may include second quantum dots for converting white light into green light in the transparent organic material, and the third light conversion layer (not shown) may include third quantum dots for converting white light into blue light in the transparent organic material.

A second quantum dot barrier layer 324 may be disposed on the light conversion layer 321 and 322. Accordingly, the light conversion layer may be disposed between the first quantum dot barrier layer 320 and the second quantum dot barrier layer 324.

It is necessary to prevent damage to the light conversion layer 321 and 322 including quantum dots during the manufacturing process or during use after manufacturing. For example, it is necessary to prevent the outgassing generated from the color filter layer 330, 331, and 332 from damaging quantum dots included in the light conversion layer 321 and 322, thereby preventing the quantum dots from failing to convert the light output from the light emitting element into the first light, the second light, or the third light.

To that end, the second quantum dot barrier layer 324 may be interposed between the light conversion layer 321 and 322 and the color filter layer 330, 331, and 332.

The second quantum dot barrier layer 324 may be formed of an inorganic material such as silicon nitride (SiNx), silicon oxide (SiOₓ), silicon oxynitride (SiOₓN_{y}), or the like to prevent the outgassing from passing therethrough. The second quantum dot barrier layer 324 may be formed of a single layer or multiple layers thereof.

An auxiliary layer 325 may be disposed on the second quantum dot barrier layer 324.

The auxiliary layer 325 may serve to increase light emission efficiency by increasing light conversion efficiency as the light output from the light emitting element 315 is re-absorbed in the light conversion layer 321 and 322.

The auxiliary layer 325 may include a semi-transmissive metal.

The auxiliary layer 325 may include one of aluminum (Al), silver (Ag), copper (Cu), magnesium (Mg), platinum (Pt), gold (Au), nickel (Ni), chromium (Cr), titanium (Ti), tungsten (W), tantalum (Ta), cobalt (Co), iron (Fe), and molybdenum (Mo), or one of alloys including at least one thereof.

For example, the auxiliary layer 325 may be an alloy including silver (Ag) and magnesium (Mg). When the auxiliary layer 325 is an Ag—Mg alloy, the atomic ratio of Ag:Mg may be 1:10 to 1:9. In other words, the atomic ratio of Mg included in the auxiliary layer 325 may be greater than the atomic ratio of Mg included in the second electrode 313.

Since the auxiliary layer 325 and the second electrode 313 each include a semi-transmissive metal material, light output from the light emitting element 315 may be repeatedly reflected between the second electrode 313 including the semi-transmissive metal and the auxiliary layer 325, or may be repeatedly reflected between the first electrode 311 and the auxiliary layer 325, thereby increasing light conversion efficiency at quantum dots included in the light conversion layer 321 and 322 and hence enhancing the efficiency of emitted light.

Further, the atomic ratio of Mg included in the auxiliary layer 325 may be greater than the atomic ratio of Mg included in the second electrode 313. In other words, the atomic ratio of Mg included in the auxiliary layer 325 may be greater than the atomic ratio of Ag. Accordingly, as a large amount of Mg is included in the auxiliary layer 325, it may serve as a moisture barrier by enhancing the ability to collect moisture.

The color filter layer 330, 331, and 332 may be disposed on the auxiliary layer 325. The color filter layers 330, 331, and 332 may be disposed to correspond to the areas of the subpixels SP1 to SP3, respectively.

The color filter layer 330, 331, and 332 may have a color corresponding to each of the at least one subpixel SP1 to SP3. The red (R) color filter layer 330 may be disposed in the red (R) subpixel SP1 area, and the green (G) color filter layer 331 and the blue (B) color filter layer 332 may be disposed in the green (G) subpixel SP2 area and the blue (B) subpixel SP3 area, respectively.

An upper substrate 326 may be disposed on the color filter layer 330, 331, and 332.

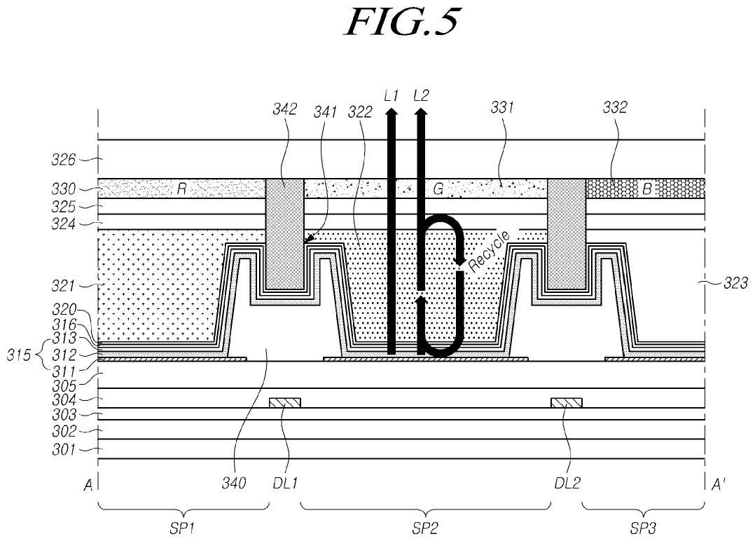

FIG. 5 is a cross-sectional view illustrating a structural feature of a display device to which a structure according to example aspects of the present disclosure is applied.

Referring to FIG. 5, the light output from the light emitting element 315 may be converted into light of a desired color in the light conversion layer 321 and 322. However, part of the light output from the light emitting element 315 may be not or little converted into light of the desired color.

Referring to FIG. 5, part L1 of the output from the light emitting element 315 of the green (G) subpixel SP2 may be converted into green light, which is the second light, in the second light conversion layer 322 and may be extracted to the outside through the green (G) color filter layer 331.

Part L2 of the light output from the light emitting element 315 may be not or little converted into green light. In this case, the part L2 of the light may not be extracted directly to the outside, but may be reflected by the auxiliary layer 325, and be reflected again by the second electrode 313 or the first electrode 311, be converted into green light, which is the second light, while passing through the second light conversion layer 322, and be then extracted to the outside through the green (G) color filter layer 331.

Accordingly, according to aspects of the present disclosure, as the auxiliary layer 325 and the second electrode 313 each include a semi-transmissive metal material, light output from the light emitting element 315 may be repeatedly reflected between the second electrode 313 including the semi-transmissive metal and the auxiliary layer 325, or may be repeatedly reflected between the first electrode 311 and the auxiliary layer 325, thereby increasing light conversion efficiency at quantum dots included in the light conversion layer 321 and 322 and hence enhancing the efficiency of emitted light.

According to aspects of the present disclosure, by applying the structure in which the black matrix 342 is deposited and inserted into the trench 341 provided in the bank layer 340, the cell gap between the light emitting element 315 and the color filter layer 330, 331, and 332 may be minimized to minimize light leakage.

According to aspects of the present disclosure, as the distance in which the light emitted from the light emitting element 315 travels outward decreases, it may be applied to display devices that require a reduction in pixel size and an increase in the number of pixels through enhancement of the field of view.

Aspects of the present disclosure described above are briefly described below.

A display device according to aspects of the present disclosure may comprise a substrate including at least one of red, green, and blue subpixels, a light emitting element including a first electrode disposed on the substrate, a light emitting layer disposed on the first electrode, and a second electrode disposed on the light emitting layer, a bank layer having an opening exposing at least a portion of the first electrode, a black matrix disposed in a trench provided in the bank layer and protruding beyond an upper surface of the bank layer, a light conversion layer disposed on the light emitting element and including quantum dots, an auxiliary layer disposed on the light conversion layer, and a color filter layer disposed on the auxiliary layer and having a color corresponding to each of the at least one subpixel.

In the display device according to aspects of the present disclosure, the first electrode may include a reflective electrode disposed on the substrate and a transparent electrode disposed on the reflective electrode, and the second electrode and the auxiliary layer may include a semi-transmissive metal.

In the display device according to aspects of the present disclosure, the first electrode may include one of aluminum (Al), silver (Ag), copper (Cu), magnesium (Mg), platinum (Pt), gold (Au), nickel (Ni), neodium (Nd), iridium (Ir), and chromium (Cr), or one of alloys including at least one thereof.

In the display device according to aspects of the present disclosure, the second electrode and the auxiliary layer may include one of aluminum (Al), silver (Ag), copper (Cu), magnesium (Mg), platinum (Pt), gold (Au), nickel (Ni), chromium (Cr), titanium (Ti), tungsten (W), tantalum (Ta), cobalt (Co), iron (Fe), and molybdenum (Mo), or one of alloys including at least one thereof.

In the display device according to aspects of the present disclosure, the second electrode and the auxiliary layer may include silver (Ag) and magnesium (Mg), and an atomic ratio of Mg included in the auxiliary layer may be larger than an atomic ratio of Mg included in the second electrode.

In the display device according to aspects of the present disclosure, a width of a lower surface of the opening may be smaller than a width of an upper surface of the opening.

In the display device according to aspects of the present disclosure, the quantum dots may fill on a lower surface of the opening, higher than on the upper surface of the bank layer.

In the display device according to aspects of the present disclosure, the quantum dots may fill lower than an upper surface of the black matrix.

In the display device according to aspects of the present disclosure, a second quantum dot barrier layer may be provided on a lower surface of the auxiliary layer to be spaced apart from the upper surface of the bank layer. The quantum dots may fill up to an area where the bank layer and the second quantum dot barrier layer are spaced apart from each other.

In the display device according to aspects of the present disclosure, the light emitting element may output blue light. The light conversion layer may include a first light conversion layer converting the blue light into red light, a second light conversion layer converting the blue light into green light, and a light transmissive layer transmitting the blue light.

In the display device according to aspects of the present disclosure, the light emitting element may output white light. The light conversion layer may include a first light conversion layer converting the white light into red light, a second light conversion layer converting the white light into green light, and a third light conversion layer converting the white light into blue light.

A display device according to aspects of the present disclosure may comprise a substrate including a light emitting element, a bank layer disposed on the substrate and defining an opening overlapping the light emitting element, the opening having an upper surface and a lower surface smaller in width than the upper surface, a first quantum dot barrier layer disposed on the light emitting element and the bank layer, a second quantum dot barrier layer disposed to be spaced apart from the first quantum dot barrier layer, an auxiliary layer disposed on the second quantum dot barrier layer, a color filter layer disposed on the auxiliary layer, and a light conversion layer disposed between the first quantum dot barrier layer and the second quantum dot barrier layer. The light conversion layer may include quantum dots which fill from the lower surface of the opening to the upper surface of the opening.

In the display device according to aspects of the present disclosure, the bank layer may have a trench in an upper surface thereof. A black matrix may be seated in the trench and protrudes beyond the upper surface of the bank layer. The quantum dots may fill higher than the upper surface of the bank layer. The quantum dots may fill lower than an upper surface of the black matrix.

In the display device according to aspects of the present disclosure, the light emitting element may include a first electrode disposed on the substrate, a light emitting layer disposed on the first electrode, and a second electrode disposed on the light emitting layer. The first electrode may include a reflective electrode and a transparent electrode disposed on the reflective electrode. The second electrode and the auxiliary layer may include a semi-transmissive metal.

In the display device according to aspects of the present disclosure, the second electrode and the auxiliary layer may include silver (Ag) and magnesium (Mg), and an atomic ratio of Mg included in the auxiliary layer may be larger than an atomic ratio of Mg included in the second electrode.

In the display device according to aspects of the present disclosure, an encapsulation layer in which a plurality of organic films and inorganic films are stacked may be disposed on the second electrode. The first quantum dot barrier layer may be disposed on the encapsulation layer.

The above description has been presented to enable any person skilled in the art to make and use the technical idea of the disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the disclosure. The above description and the accompanying drawings provide an example of the technical idea of the disclosure for illustrative purposes only. Thus, it is intended that the present disclosure covers the modifications and variations of the aspects provided they come within the scope of the appended claims and their equivalents.

What is claimed is:

1. A display device, comprising:
a substrate including at least one of red, green, and blue subpixels;
a light emitting element including a first electrode disposed on the substrate, a light emitting layer disposed on the first electrode, and a second electrode disposed on the light emitting layer;
a bank layer having an opening exposing at least a portion of the first electrode;
a black matrix disposed in a trench provided in the bank layer and protruding beyond an upper surface of the bank layer;
a light conversion layer disposed on the light emitting element and including quantum dots;
an auxiliary layer disposed on the light conversion layer; and
a color filter layer disposed on the auxiliary layer and having a color corresponding to each of the at least one subpixel.

2. The display device of claim 1, wherein the first electrode includes a reflective electrode disposed on the substrate and a transparent electrode disposed on the reflective electrode, and
wherein the second electrode and the auxiliary layer include a semi-transmissive metal.

3. The display device of claim 1, wherein the second electrode and the auxiliary layer include silver and magnesium, and
wherein an atomic ratio of magnesium included in the auxiliary layer is larger than an atomic ratio of magnesium included in the second electrode.

4. The display device of claim 1, wherein a width of a lower surface of the opening is smaller than a width of an upper surface of the opening.

5. The display device of claim 1, wherein the quantum dots fill on a lower surface of the opening, higher than on the upper surface of the bank layer.

6. The display device of claim 5, wherein the quantum dots fill lower than an upper surface of the black matrix.

7. The display device of claim 1, wherein a second quantum dot barrier layer is provided on a lower surface of the auxiliary layer to be spaced apart from the upper surface of the bank layer, and
wherein the quantum dots fill up to an area where the bank layer and the second quantum dot barrier layer are spaced apart from each other.

8. The display device of claim 1, wherein the light emitting element outputs blue light, and
wherein the light conversion layer includes:
a first light conversion layer converting the blue light into red light;
a second light conversion layer converting the blue light into green light; and
a light transmissive layer transmitting the blue light.

9. The display device of claim 1, wherein the light emitting element outputs white light, and
wherein the light conversion layer includes:
a first light conversion layer converting the white light into red light;
a second light conversion layer converting the white light into green light; and
a third light conversion layer converting the white light into blue light.

10. A display device, comprising:
a substrate including a light emitting element;
a bank layer disposed on the substrate and defining an opening overlapping the light emitting element, the opening having an upper surface and a lower surface smaller in width than the upper surface;
a first quantum dot barrier layer disposed on the light emitting element and the bank layer;
a second quantum dot barrier layer disposed to be spaced apart from the first quantum dot barrier layer;
an auxiliary layer disposed on the second quantum dot barrier layer;
a color filter layer disposed on the auxiliary layer; and
a light conversion layer disposed between the first quantum dot barrier layer and the second quantum dot barrier layer,
wherein the light conversion layer includes quantum dots which fill from the lower surface of the opening to the upper surface of the opening.

11. The display device of claim 10, wherein the bank layer has a trench in an upper surface thereof,
wherein a black matrix is seated in the trench and protrudes beyond the upper surface of the bank layer,
wherein the quantum dots fill higher than the upper surface of the bank layer, and
wherein the quantum dots fill lower than an upper surface of the black matrix.

12. The display device of claim 10, wherein the light emitting element includes a first electrode disposed on the substrate, a light emitting layer disposed on the first electrode, and a second electrode disposed on the light emitting layer,
wherein the first electrode includes a reflective electrode and a transparent electrode disposed on the reflective electrode, and
wherein the second electrode and the auxiliary layer include a semi-transmissive metal.

13. The display device of claim 12, wherein the second electrode and the auxiliary layer include silver and magnesium, and
wherein an atomic ratio of magnesium included in the auxiliary layer is larger than an atomic ratio of magnesium included in the second electrode.

14. The display device of claim 12, wherein an encapsulation layer in which a plurality of organic films and inorganic films are stacked is disposed on the second electrode, and
wherein the first quantum dot barrier layer is disposed on the encapsulation layer.
